(19) United States
(12) Patent Application Publication
(10) Pub. No.: US 2024/0332040 A1
(43) Pub. Date: Oct. 3, 2024

(54) SUBSTRATE PROCESSING APPARATUS

(71) Applicant: Tokyo Electron Limited, Tokyo (JP)

(72) Inventor: Koukichi HIROSHIRO, Kumamoto (JP)

(21) Appl. No.: 18/612,873

(22) Filed: Mar. 21, 2024

(30) Foreign Application Priority Data
Mar. 28, 2023 (JP) 2023-051476

(51) Int. Cl. H01L 21/67

(52) U.S. Cl. CPC H01L 21/67069

(57) ABSTRACT

A substrate liquid-processing apparatus includes: an irradiation unit that radiates an etching energy beam having a wavelength of 185 nm or less toward the peripheral edge of a substrate; a gas supply unit that supplies an oxygen-containing gas or ozone gas to the peripheral edge of the substrate; a peripheral edge heating unit that is arranged to be located above the substrate, extends in a circular arc or annular shape along the peripheral edge of the substrate, and heats the peripheral edge of the substrate by radiating light to the peripheral edge of the substrate; a light shielding member that is disposed between the substrate and the peripheral edge heating unit, and blocks at least a portion of the light from the peripheral edge heater toward the peripheral edge of the substrate; and a driving unit that changes the separation distance between the substrate and the light shielding member.

### CROSS-REFERENCE TO RELATED APPLICATIONS

The present application is based on and claims priority from Japanese Patent Application No. 2023-051476, filed on Mar. 28, 2023, with the Japan Patent Office, the disclosure of which is incorporated herein in its entirety by reference.

### TECHNICAL FIELD

The present disclosure relates to a substrate processing apparatus.

### BACKGROUND

Japanese Patent Laid-open Publication No. 2011-514679 discloses a substrate processing apparatus that removes a layer deposited on the peripheral edge of a substrate using plasma by supplying a process gas to a chamber that accommodates the substrate and turning the process gas into plasma.

### SUMMARY

A substrate processing apparatus includes; an irradiation unit that radiates an etching energy beam having a wavelength of 185 nm or less toward the peripheral edge of a substrate; a gas supply unit that supplies an oxygen-containing gas or ozone gas to a peripheral edge of the substrate; a peripheral edge heating unit that is arranged to be located above the substrate, extends in a substantially circular arc shape or a substantially annular shape along the peripheral edge of the substrate, and heats the peripheral edge of the substrate by radiating light to the peripheral edge of the substrate; a light shielding member disposed between the substrate and the peripheral edge heating unit, the light shielding member being configured to block at least a portion of the light radiated from the peripheral edge heating unit toward the peripheral edge of the substrate; and a driving unit configured to change the separation distance between the substrate and the light shielding member.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a perspective view illustrating an example of a substrate processing system.

FIG. 2 is a cross-sectional view taken along line II-II in FIG. 1.

FIG. 3 is a cross-sectional view schematically illustrating an example of the configuration of an etching unit.

FIG. 4 is a block diagram illustrating an example of main components of a substrate processing system.

FIG. 5 is a schematic view illustrating an example of the hardware configuration of a controller.

FIGS. 6A and 6B are schematic cross-sectional views illustrating the operation of the etching unit.

FIGS. 7A and 7B are partial cross-sectional views schematically illustrating the configuration of another example of the etching unit.

FIGS. 8A and 8B are partial cross-sectional views schematically illustrating another example of the configuration of the etching unit.

FIG. 9 is a partial cross-sectional view schematically illustrating another example of the configuration of the etching unit.

FIG. 10 is a partial cross-sectional view schematically illustrating another example of the configuration of the etching unit.

FIG. 11A is a graph showing the experimental results of Experimental Example 1, and FIG. 11B is a graph showing the experimental results of Experimental Example 2.

FIG. 12A is a graph showing the experimental results of Experimental Example 3, and FIG. 12B is a graph showing the experimental results of Experimental Example 4.

FIG. 13A is a graph showing the relationship between a gap and an etching rate when the substrates were heated at 400° C. in Experimental Examples 1 to 3, and FIG. 13B is a graph showing the relationship between an ultraviolet irradiation time and an etching amount when the substrates were heated at 300° C. with the gap set to 1.2 mm in Experimental Examples 1 to 3.

FIG. 14A is a graph showing the experimental results of Experimental Example 5, and FIG. 14B is a graph showing the experimental results of Experimental Examples 6 and 7.

### DETAILED DESCRIPTION

The foregoing summary is illustrative only and is not intended to be in any way limiting. In addition to the illustrative aspects, embodiments, and features described above, further aspects, embodiments, and features will become apparent by reference to the drawings and the following detailed description.

In the following description, the same reference numerals will be used for the same elements or elements having the same function, and redundant descriptions will be omitted. In this specification, the top, bottom, right, and left of the drawings are based on the directions of the symbols in the drawings.

### [Configuration of Substrate Processing System]

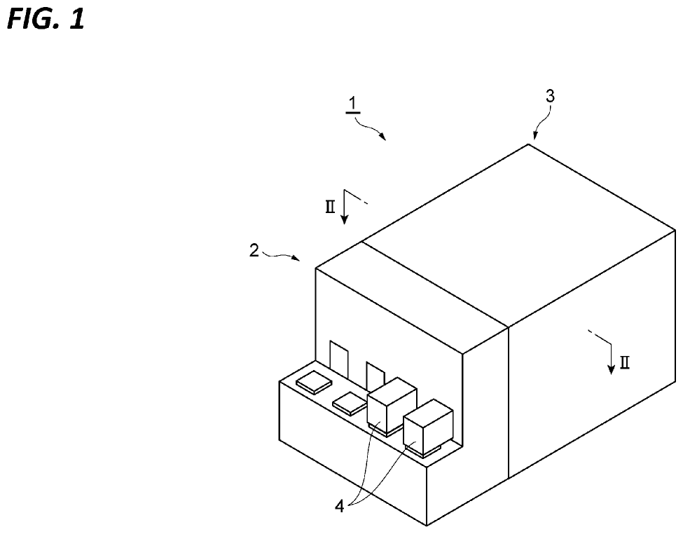

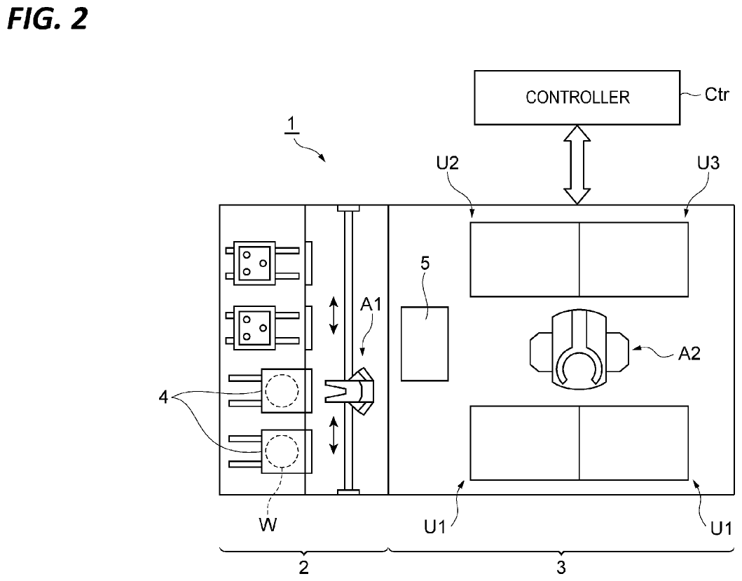

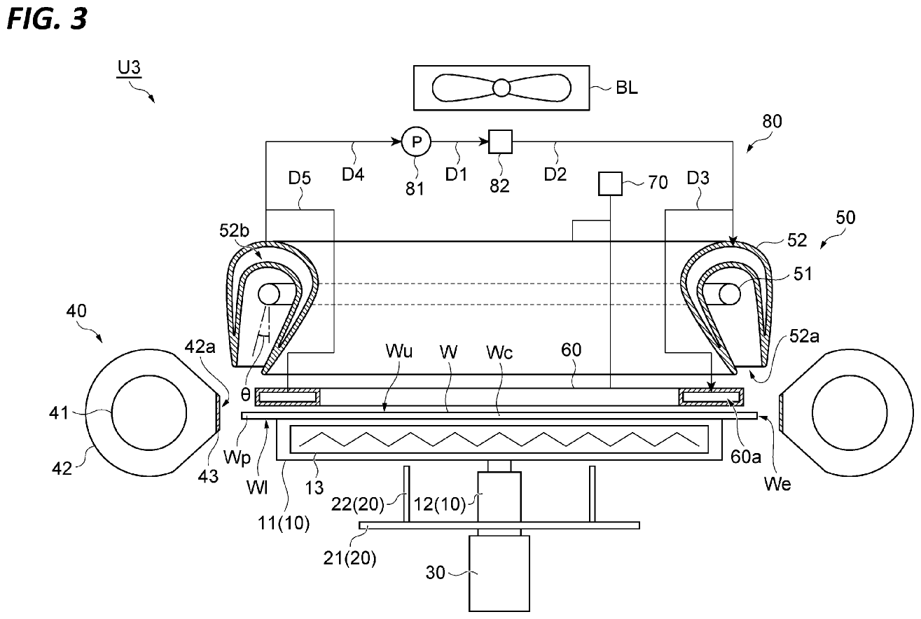

First, the configuration of a substrate processing system 1 (substrate processing apparatus) will be described with reference to FIGS. 1 and 2. The substrate processing system 1 is configured to form a coating film on the top surface Wu of a substrate W by applying a coating liquid. The substrate processing system 1 is configured to cure the coating film through heat treatment to form a protective film (not illustrated) on the top surface Wu of the substrate W. The substrate processing system 1 is configured to remove the protective film at the peripheral edge Wp (see FIG. 3) of the substrate W by etching.

The substrate W may have a disk shape, or may have a plate shape other than a circular shape, such as a polygonal shape. The substrate W may have a cutout portion in which a portion is cut out. The cutout portion may be, for example, a notch (e.g., a U-shaped or V-shaped groove) or a straight portion extending in a straight line (so-called an orientation flat). The substrate W may be, for example, a semiconductor substrate (silicon wafer), a glass substrate, a mask substrate, a flat panel display (FPD) substrate, or other various substrates. The diameter of the substrate W may be, for example, about 200 mm to 450 mm.

The protective film may be a carbon-containing film. The carbon-containing film may be, for example, a diamond film, an amorphous carbon film, or an oxygen-containing spin-on carbon (SOC) film. That is, the carbon-containing film may contain, as an element other than carbon, an element of which atoms are gaseous by themselves, or an element which combines with oxygen to become gaseous at normal pressure. Herein, “the surface of a substrate W” means the outermost surface of the substrate W. For example, in an example in which a protective film is formed on a substrate W, the surface of the protective film may be the “surface of the substrate W.”

As illustrated in FIGS. 1 and 2, the substrate processing system 1 includes a loading/unloading station 2, a processing station 3, and a controller Ctr (control unit). The loading/unloading station 2 and the processing station 3 may be arranged, for example, horizontally in a line.

The loading/unloading station 2 perform loading of substrates W into the substrate processing system 1 and unloading of substrates W from the substrate processing system 1. The loading/unloading station 2 may support, for example, a plurality of carriers 4 for substrates W. The carriers 4 are each configured to accommodate at least one substrate W in a sealed state. The loading/unloading station 2 has a built-in transfer arm A1, as illustrated in FIG. 2. The transfer arm A1 is configured to take out a substrate W from a carrier 4 and deliver the substrate to a shelf unit 5 of the processing station 3, and to receive the substrate W from the shelf unit 5 of the processing station 3 and return the substrate W into the carrier 4.

The processing station 3 includes at least one liquid processing unit U1, at least one heat treatment unit U2, at least one etching unit U3 (a substrate processing apparatus), and a transfer arm A2 configured to transfer substrates W to these units. The transfer arm A2 is configured to take out a substrate W from the shelf unit 5 and deliver the substrate W to each unit, and also to receive the substrate W from each unit and return the substrate to the shelf unit 5.

The liquid processing unit U1 is configured to supply a processing liquid for forming a protective film to the top surface Wu of the substrate W, and execute a process of forming a coating film on the top surface Wu of the substrate W. The heat treatment unit U2 is configured to execute a process of curing the coating film formed in the liquid treatment unit U1 by heat treatment and forming a protective film on the top surface Wu of the substrate W. In addition, when the processing liquid is supplied to the top surface Wu of the substrate W in the liquid processing unit U1, the processing liquid may flow around the end surface We (see FIG. 3) of the substrate W and reach the bottom surface Wl of the substrate W. In this case, the protective film may be formed from the top surface Wu of the substrate W, around the end surface We, and up to the bottom surface Wl of the peripheral edge Wp.

The etching unit U3 is configured to execute a process of removing the protective film on the peripheral edge Wp of the substrate W by etching. Details of the etching unit U3 will be described later.

The controller Ctr is configured to partially or completely control the substrate processing system 1. The details of the controller Ctr will be described later.

### [Configuration of Etching Unit]

Next, with reference to FIG. 3, the configuration of the etching unit U3 will be described. The etching unit U3 includes a rotary holding unit 10, a support unit 20, a lifting unit 30, an irradiation unit 40, a peripheral edge heating unit 50, a light shielding member 60, a driving unit 70, a cooling unit 80, and a blower BL (a supply unit).

The rotary holding unit 10 has a holding unit 11 and a rotary driving unit 12. The holding unit 11 is configured to hold a horizontally arranged substrate W from below. The holding unit 11 includes a center heating unit 13. The center heating unit 13 is configured to operate based on an operation signal from the controller Ctr, and mainly heat the central portion Wc of the substrate W held by the holding unit 11. The center heating unit 13 may be configured, for example, to heat the central portion Wc of the substrate W to 400° C. or lower, or may be configured to heat the central portion Wc of the substrate W to about 50° C. to 400° C.

Although not illustrated, the center heating unit 13 may include a plurality of heating regions arranged in the radial direction of the substrate W. The plurality of heating regions may be arranged, for example, concentrically from the center of the substrate W toward the outer circumference. The plurality of heating regions may each have a built-in heat source (e.g., a heater). In this case, different temperatures may be set for respective heating regions.

The rotary driving unit 12 is configured to operate based on an operation signal from the controller Ctr and rotate the substrate W held by the holding unit 11. The rotary driving unit 12 may rotate the holding unit 11 around a vertical axis passing through the center of the substrate W using, for example, an electric motor as a power source.

The support unit 20 is arranged below the holding unit 11. The support unit 20 includes a base 21 and a plurality of support pins 22 that protrude upward from the base 21. The tips of the support pins 22 may be inserted through through-holes (not illustrated) provided in the holding unit 11.

The lifting unit 30 is configured to operate based on an operation signal from the controller Ctr and to move the rotary holding unit 10 up and down. The substrate W held by the rotary holding unit 10 is displaced up and down as the rotary holding unit 10 is raised and lowered by the lifting unit 30. As a result, the separation distance between the top surface Wu of the substrate W and the peripheral edge heating unit 50 and the separation distance between the top surface Wu of the substrate W and the light shielding member 60 are changed. The lifting unit 30 may be, for example, an electric motor or an air cylinder.

The lifting unit 30 may be configured to move the support unit 20 up and down. That is, the tips of the support pins 22 may be configured to be able to protrude and retract from the top surface of the holding unit 11 by the lifting unit 30. When the lifting unit 30 raises the support unit 20, the tips of the support pins 22 protrude above the top surface of the holding unit 11, and when the lifting unit 30 lowers the support unit 20, the tips of the support pins 22 descend below the top surface of the holding unit 11. In the state where the tips of the support pins 22 protrude above the top surface of the holding unit 11, the substrate W is supported by the tips of the support pins 22 when the substrate W is loaded into/unloaded from the etching unit U3.

The irradiation unit 40 is disposed on the side of the substrate W while the substrate W is held by the rotary holding unit 10. The irradiation unit 40 may have a substantially circular arc shape or a substantially annular shape along the peripheral edge Wp of the substrate W so as to surround the peripheral edge Wp of the substrate W from the outside. Here, the substantially circular arc-shaped irradiation unit 40 may include a major arc-shaped irradiation unit 40 that surrounds most of the peripheral edge Wp of the substrate W from the outside but is partially interrupted. The substantially circular arc-shaped irradiation unit 40 may include a plurality of arc-shaped irradiation units 40 that partially surround the peripheral edge Wp of the substrate W from the outside and are aligned along the peripheral edge Wp of the substrate W so as to form a substantially circular shape as a whole. The substantially annular irradiation unit 40 may include an endless irradiation unit 40 that surrounds the entire peripheral edge Wp of the substrate W from the outside. The irradiation unit 40 includes a light source 41, a reflective member 42, and a window 43.

The light source 41 is configured to operate based on an operation signal from the controller Ctr, and radiate an etching energy beam having a wavelength of 185 nm or less toward the peripheral edge Wp of the substrate W. The light source 41 may have a substantially circular arc shape or a substantially ring shape so as to surround the peripheral edge Wp of the substrate W from the outside. Here, the substantially circular arc-shaped light source 41 may include a major arc-shaped light source 41 that surrounds most of the peripheral edge Wp of the substrate W from the outside but is partially interrupted. The substantially circular arc-shaped light source 41 may include a plurality of arc-shaped light sources 41 that partially surround the peripheral edge Wp of the substrate W from the outside and are aligned along the peripheral edge Wp of the substrate W so as to form a substantially circular shape as a whole. The substantially annular light source 41 may include an endless light source 41 that surrounds the entire peripheral edge Wp of the substrate W from the outside.

The energy beam may be, for example, an ultraviolet beam. The main wavelength of the energy beam may be 185 nm or less, 172 nm or less, 165 nm or less, 150 nm or less, or 120 nm or less, or 100 nm or less. When the main wavelength of the energy beam is 172 nm, the light source 41 may be a xenon excimer UV lamp. When the main wavelength of the energy beam is 146 nm, the light source 41 may be a krypton discharge lamp. When the main wavelength of the energy beam is 126 nm, the light source 41 may be an argon discharge lamp.

The reflective member 42 has a substantially U-shaped cross section so as to cover the periphery of the light source 41. That is, the reflective member 42 includes an opening 42a that is open toward the inside. The opening 42a faces the end surface We of the peripheral edge Wp of the substrate W when the substrate W is held by the rotary holding unit 10. The reflective member 42 is configured to reflect, toward the opening 42a side, light radiated from the light source 41 toward the rear side of the reflective member 42 (the wall surface side of the reflective member 42 opposite to the opening 42a). The light reflected by the reflective member 42 is radiated toward the peripheral edge Wp of the substrate W through the opening 42a. Therefore, the peripheral edge Wp of the substrate W is more intensively irradiated with the energy beam. In this case, bonds between atoms of the film can be more easily broken. Therefore, it becomes possible to obtain a higher etching rate.

The window 43 is configured such that the energy beam radiated from the light source 41 can pass therethrough. The material of the window 43 may be appropriately selected depending on the wavelength of the energy beam radiated from the light source 41. For example, when the main wavelength of the energy beam is 165 nm or more, quartz glass may be selected as the material for the window 43. When the main wavelength of the energy beam is 150 nm or more, calcium fluoride may be selected as the material for the window 43. When the main wavelength of the energy beam is 120 nm or more, magnesium fluoride may be selected as the material for the window 43.

The window 43 is attached to the opening 42a of the reflective member 42 so as to seal the opening 42a. Therefore, the airtightness within the reflective member 42 is maintained. For example, an inert gas (e.g., nitrogen gas) may be filled in the internal space defined by the reflective member 42 and the window 43. The straight-line distance between the surface of the window 43 and the end surface We of the substrate W may be set to about 1 mm.

The peripheral edge heating unit 50 is disposed above the peripheral edge Wp of the substrate W, and is configured to heat the peripheral edge Wp of the substrate W from above. The peripheral edge heating unit 50 may be configured to heat the peripheral edge Wp of the substrate W to 400° C. or higher. The peripheral edge heating unit 50 may have a substantially circular arc shape or a substantially annular shape along the peripheral edge Wp of the substrate W. The peripheral edge heating unit 50 may be located so as to overlap the peripheral edge Wp of the substrate W when viewed from above. Here, the substantially circular arc-shaped peripheral edge heating unit 50 may include a substantially major arc-shaped peripheral edge heating unit 50 that is partially interrupted. The substantially circular arc-shaped peripheral edge heating unit 50 may include a plurality of arc-shaped peripheral edge heating units 50 aligned along the peripheral edge Wp of the substrate W so as to form a substantially circular shape as a whole. The substantially annular peripheral edge heating unit 50 may include an endless peripheral edge heating unit 50. The peripheral edge heating unit 50 includes a light source 51 and a housing 52.

The light source 51 may be an infrared lamp that heats the peripheral edge Wp of the substrate W by radiating light to the peripheral edge Wp. The light source 51 may irradiate the peripheral edge Wp of the substrate W with light continuously, intermittently, or instantaneously. The light source 51 may have a substantially circular arc shape or a substantially annular shape along the peripheral edge Wp of the substrate W. Here, the substantially circular arc-shaped light source 51 may include a substantially major arc-shaped light source 51 that is partially interrupted. The substantially circular arc-shaped light source 51 may include a plurality of arc-shaped light sources 51 aligned along the peripheral edge Wp of the substrate W so as to form a substantially circular shape as a whole. The substantially annular light source 51 may include an endless peripheral edge heating unit 50.

The housing 52 has a substantially U-shaped cross section so as to cover the periphery of the light source 51. That is, the housing 52 includes an opening 52a that is open downward. As illustrated in FIG. 3, the opening 52a is open obliquely downward. In the example of FIG. 3, the opening 52a may be open obliquely downward and radially outward of the substrate W. In this case, the light from the light source 51 is radiated obliquely downward and radially outward of the substrate W through the opening 52a. The inclination angle θ of the opening 52a with respect to the vertical direction may be, for example, about 1° to 20°, or about 2° to 5°.

The inner circumferential surface of the housing 52 is made of a reflective member. The inner circumferential surface of the housing 52 is configured to reflect, toward the opening 52a side, light radiated from the light source 51 toward the rear side of the inner circumferential surface of the housing 52 (the side of the inner circumferential surface of the housing 52 opposite to the opening 52a). The light reflected by the inner circumferential surface of the housing 52 is radiated toward the peripheral edge Wp of the substrate W through the opening 52a. Therefore, the peripheral edge Wp of the substrate W is heated more intensively.

An internal space 52b is defined inside the housing 52. The internal space 52b is configured such that a coolant (described later) supplied from the cooling unit 80 flows therethrough.

The light shielding member 60 is arranged between the substrate W held by the rotary holding unit 10 and the peripheral edge heating unit 50. The light shielding member 60 is configured to block at least a portion of the light radiated from the peripheral edge heating unit 50 toward the peripheral edge Wp of the substrate W. That is, the light radiated from the peripheral edge heating unit 50 is arranged in a shape along the outer peripheral edge of the light shielding member 60 and is radiated toward the substrate W located below the light shielding member 60. As illustrated in FIG. 3, the light shielding member 60 may have a circular annular shape or may have a circular shape. In the example of FIG. 3, the light shielding member 60 has a diameter (outer diameter) smaller than the diameter of the substrate W.

An internal space 60a is defined inside the light shielding member 60. The internal space 60a is configured such that a coolant (described later) supplied from the cooling unit 80 flows therethrough.

The driving unit 70 is configured to operate based on an operation signal from the controller Ctr and change the separation distance between the substrate W and the light shielding member 60. The driving unit 70 may be configured with, for example, a linear actuator. In the example of FIG. 3, the driving unit 70 is connected to the peripheral edge heating unit 50 and the light shielding member 60 and is configured to move the driving unit and the peripheral edge heating unit up and down simultaneously.

The cooling unit 80 is configured to cool the peripheral edge heating unit 50 and the light shielding member 60. The cooling unit 80 includes pipes D1 to D5, a pump 81, and a temperature control unit 82.

The pipe D1 interconnects the pump 81 and the temperature control unit 82. The pipe D2 interconnects the temperature control unit 82 and the internal space 52b of the housing 52 of the peripheral edge heating unit 50. The pipe D3 branches off and extends from the middle of the pipe D2, and interconnects the middle of the pipe D2 and the internal space 60a of the light shielding member 60. The pipe D4 interconnects the internal space 52b of the housing 52 of the peripheral edge heating unit 50 and the pump 81. The connection point between the pipe D4 and the internal space 52b may be separated from the connection point between the pipe D2 and the internal space 52b, or may be located opposite to the connection point between the pipe D2 and the internal space 52b with the center of the peripheral edge heating unit 50 interposed therebetween. The pipe D5 branches off and extends from the pipe D4, and interconnects the internal space 60a of the light shielding member 60 and the middle of the pipe D4. The connection point between the pipe D5 and the internal space 60a may be separated from the connection point between the pipe D3 and the internal space 60a, or may be located opposite to the connection point between the pipe D3 and the internal space 60a with the center of the shielding member 60 interposed therebetween.

The pump 81 is configured to operate based on an operation signal from the controller Ctr, suction the coolant flowing in the internal spaces 52b and 60a through the pipes D4 and D5, and supply the coolant suctioned through the pipe D1 to the temperature control unit 82. The temperature control unit 82 is configured to operate based on an operation signal from the controller Ctr, and regulate the temperature of the coolant supplied from the pump 81. The temperature control unit 82 may be configured to cool the coolant such that the coolant reaches a predetermined set temperature. The temperature control unit 82 is configured to supply a temperature-controlled coolant to the internal spaces 52b and 60a through the pipes D2 and D3. The coolant may be, for example, air or water.

The coolant is circulated through the pipes D1 to D5 and the internal spaces 52b and 60a by the pump 81. Therefore, the housing 52 and the light shielding member 60, which are heated by the irradiation of light from the light source 51, are cooled down. Therefore, since the housing 52 and the light shielding member 60 are suppressed from being deformed, the peripheral edge Wp of the substrate W can be irradiated with light from the peripheral edge heating unit 50 with higher precision.

The blower BL is configured to operate based on an operation signal from the controller Ctr, and generate a down blow toward the substrate W. When the wavelength of the energy beam radiated from the light source 41 is an ultraviolet beam with a wavelength of 185 nm or less, air is supplied toward the substrate W by the operation of the blower BL, so that the ultraviolet light is absorbed by oxygen molecules and turns into ozone in the space between the window 43 and the peripheral edge Wp of the substrate W. Then, the protective film at the peripheral edge Wp of the substrate W reacts with the ozone, and the protective film is etched. At this time, by rotating the substrate W using the rotary holding unit 10, the bias of energy beam irradiation on the peripheral edge Wp of the substrate W may be evened out.

### [Details of Controller]

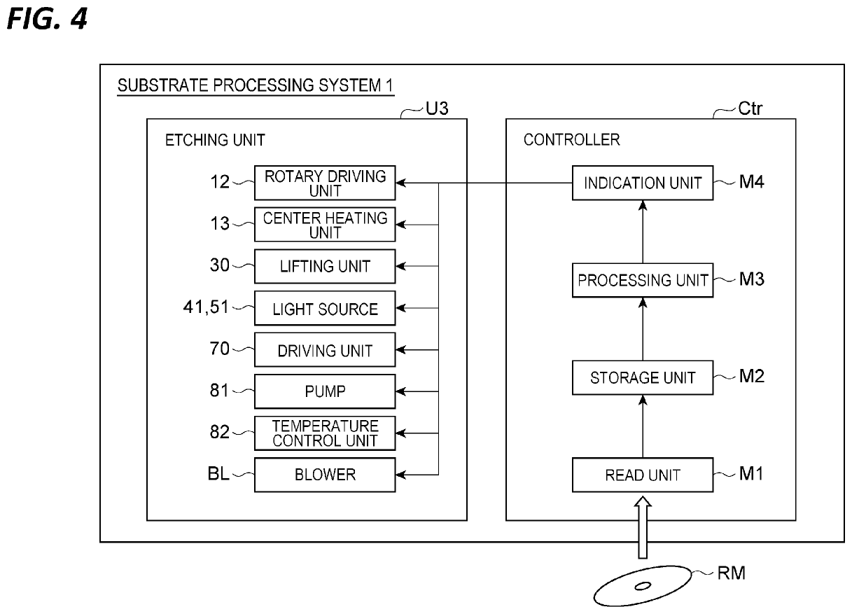

As illustrated in FIG. 4, the controller Ctr includes, as function modules, a read unit M1, a storage unit M2, a processing unit M3, and an indication unit M4. These function modules merely correspond to the functions of the controller Ctr divided into a plurality of modules for convenience and do not necessarily mean that the hardware constituting the controller Ctr is divided into such modules. Each function module is not limited to that implemented by executing a program, and may be implemented by a dedicated electric circuit (e.g., a logic circuit) or an integrated circuit in which the dedicated electric circuit is integrated (an application-specific integrated circuit (ASIC)).

The read unit M1 is configured to read a program from a computer-readable recording medium RM. The recording medium RM is recorded with a program for operating each component of the substrate processing system 1 including the etching unit U3. The recording medium RM may be, for example, a semiconductor memory, an optical recording disk, a magnetic recording disk, or a magneto-optical recording disk. Hereinbelow, respective components of the substrate processing system 1 may include a rotary driving unit 12, a center heating unit 13, a lifting unit 30, light sources 41 and 51, a driving unit 70, a pump 81, a temperature control unit 82, and a blower BL.

The storage unit M2 is configured to store various data. The storage unit M2 may store, for example, a program read from the recording medium RM by the read unit M1, and setting data input via an external input device (not illustrated) by an operator.

The processing unit M3 is configured to process various data. The processing unit M3 may generate a signal for operating each component of the substrate processing system 1 based on, for example, various data stored in the storage unit M2.

The indication unit M4 is configured to transmit an operation signal generated by the processing unit M3 to each component of the substrate processing system 1.

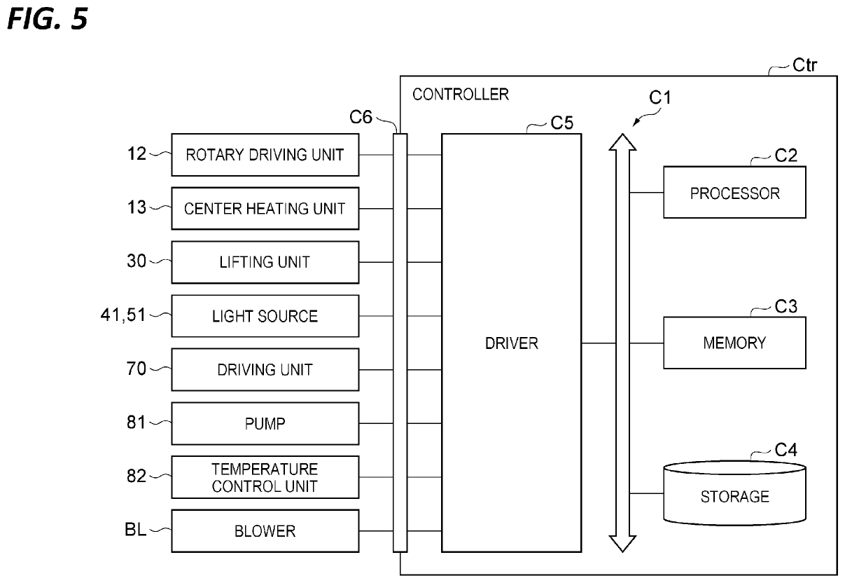

The hardware of the controller Ctr may be configured with, for example, one or more control computers. As illustrated in FIG. 5, the controller Ctr may include a circuit C1 as a hardware configuration. The circuit C1 may be configured with an electric circuit element (circuitry). The circuit C1 may include, for example, a processor C2, memory C3, a storage C4, a driver C5, and an input/output port C6.

The processor C2 may be configured to implement each of the above-described function modules by executing a program in cooperation with at least one of the memory C3 and the storage C4 and executing input/output of a signal via the input/output port C6. The memory C3 and the storage C4 may function as the storage unit M2. The driver C5 may be a circuit configured to individually drive each component of the substrate processing system 1. The input/output port C6 may be configured to mediate input/output of a signal between the driver C5 and each component of the substrate processing system 1.

The substrate processing system 1 may include one controller Ctr, or may include a controller group (a control part) including a plurality of controllers Ctr. When the substrate processing system 1 includes a controller group, each of the above-mentioned function modules may be implemented by a single controller Ctr, or may be implemented by a combination of two or more controllers Ctr. When the controller Ctr is configured with a plurality of computers (the circuit C1), each of the above-mentioned function modules may be implemented by a single computer (the circuit C1), or may be implemented by a combination of two or more computers (the circuit C1). The controller Ctr may include a plurality of processors C2. In this case, each of the function modules may be implemented by a single processor C2, or may be implemented by a combination of two or more processors C2.

### [Action]

According to the above examples, the peripheral edge Wp of a substrate W is irradiated with a relatively high-energy beam having a wavelength of 185 nm or less, so that bonds between atoms of a film provided on the peripheral edge Wp of the substrate W can be easily cut. In addition, since air is supplied to the peripheral edge Wp of the substrate W, atoms cut by the energy beam tend to bond with oxygen atoms without recombining. Furthermore, since the peripheral edge Wp of the substrate W is heated by the peripheral edge heating unit 50, the cutting of bonds between atoms by the energy beam and the bonding of oxygen atoms to the atoms cut by the energy beam tend to become more active. As a result, it becomes possible to etch a relatively hard film provided on the peripheral edge Wp of the substrate W at a relatively high etching rate without using plasma.

According to the above-described examples, the light shielding member 60 blocks at least a portion of the light radiated from the peripheral edge heating unit 50 toward the peripheral edge Wp of the substrate W. Therefore, the peripheral edge Wp of the substrate W is irradiated with light in a shape along the outer peripheral edge of the light shielding member 60. Therefore, since light is precisely radiated onto the peripheral edge Wp of the substrate W based on the shape of the outer peripheral edge of the light shielding member 60, it becomes possible to etch a relatively hard film provided on the peripheral edge Wp of the substrate W with high precision.

According to the above examples, the separation distance between the substrate W and the light shielding member 60 is changed by the driving unit 70. Therefore, the range of light radiated from the peripheral edge heating unit 50 to the peripheral edge Wp of the substrate W changes depending on this change in separation distance. Therefore, it becomes possible to appropriately regulate the region in which a relatively hard film provided on the peripheral edge Wp of the substrate W is etched.

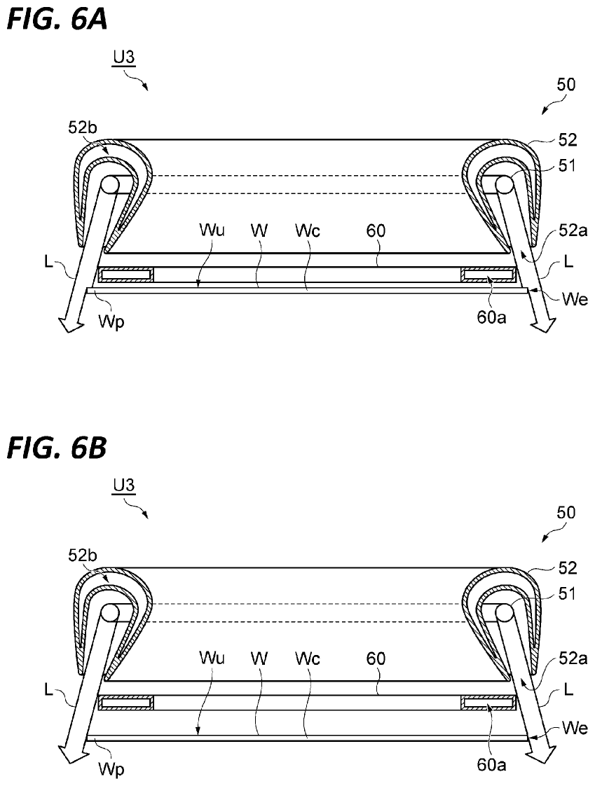

Specifically, as illustrated in FIG. 6A, the driving unit 70 may lower the peripheral edge heating unit 50 and the light shielding member 60 such that the separation distance between the substrate W and the light shielding member 60 decreases. In this case, the light L from the peripheral edge heating unit 50 after being shaped into a shape along the outer peripheral edge of the light shielding member 60 is radiated onto a predetermined region of the peripheral edge Wp of the substrate W. The region may be adjusted by the separation distance between the substrate W and the light shielding member 60 and the inclination angle θ of the opening 52a. In addition, on the top surface Wu of the peripheral edge Wp of the substrate W, the region may be in a range up to 1.5 mm from the outer peripheral edge of the substrate W, may be in a range up to 1 mm from the outer peripheral edge of the substrate W, or may be in a range up to 0.75 mm from the outer peripheral edge of the substrate W.

Meanwhile, as illustrated in FIG. 6B, the driving unit 70 may lower the peripheral edge heating unit 50 and the light shielding member 60 such that the separation distance between the substrate W and the light shielding member 60 increases. In this case, the light L from the peripheral edge heating unit 50 after being shaped into a shape along the outer peripheral edge of the light shielding member 60 passes through a space outside the peripheral edge Wp of the substrate W and is not radiated to the peripheral edge Wp of the substrate W.

In this way, the driving unit 70 is configured to move the peripheral edge heating unit 50 and the light shielding member 60 up and down between a first position illustrated in FIG. 6A and a second position illustrated in FIG. 6B. The first position is a position where the light shielding member 60 partially blocks the light L from the peripheral edge heating unit 50 such that the light from the peripheral edge heating unit 50 reaches the peripheral edge Wp of the substrate W (see FIG. 6A). The second position is a position where the light shielding member 60 blocks the light L from the peripheral edge heating unit 50 such that the light from the peripheral edge heating unit 50 does not reach the peripheral edge Wp of the substrate W (see FIG. 6B). In this case, while the irradiation of light L from the peripheral edge heating unit 50 continues, the light is blocked from reaching the peripheral edge Wp of the substrate W. Therefore, it becomes possible to efficiently process the substrate W without waiting for the period during which the irradiation of light L from the peripheral edge heating unit 50 changes from an off state to an on state and reaches a steady state. Furthermore, it becomes possible to suppress the light source 51 from being deteriorated due to repeated turning on and off of the light from the peripheral edge heating unit 50.

According to the above examples, the housing 52 covers the periphery of the light source 51 and includes the opening 52a that is open toward the peripheral edge Wp of the substrate W. Therefore, the light from the light source 51 and the light reflected from the inner surface of the housing 52 are radiated onto the peripheral edge Wp of the substrate W through the opening 52a. Therefore, it becomes possible to efficiently use the optical energy of the light source 51 to heat the peripheral edge Wp of the substrate W.

According to the above examples, the opening 52a is open obliquely downward and radially outward of the substrate W. Therefore, thanks to the fact that the separation distance between the substrate W and the light shielding member 60 is changed by the driving unit 70, it becomes possible to change the range of light radiated from the peripheral edge heating unit 50 to the peripheral edge Wp of the substrate W.

According to the above examples, the peripheral heating part 50 is configured to heat the peripheral edge Wp of the substrate W to 400° C. or higher, and the center heating unit 13 is configured to heat the central portion Wc of the substrate W to 400° C. or lower. In this case, since the peripheral edge Wp of the substrate W is heated to 400° C. or higher, the cutting of bonds between atoms by the energy beam and the bonding of oxygen atoms to the atoms broken by the energy beam tend to become more active. Meanwhile, since the central portion Wc of the substrate W is heated to 400° C. or lower, the temperature difference between the peripheral edge Wp and the central portion Wc of the substrate W becomes small, so that the substrate W is less likely to warp. Therefore, thanks to the fact that the amount of heating to the central portion Wc of the substrate W is relatively low as well, electronic components formed in the central portion Wc of the substrate W are less likely to be damaged. As described above, it becomes possible to etch a film on the peripheral edge Wp of the substrate W at a relatively high etching rate while suppressing damage to the electronic components formed in the central portion Wc of the substrate W.

According to the above examples, the irradiation unit 40 extends in a substantially circular arc shape or a substantially annular shape along the peripheral edge Wp of the substrate W so as to surround the peripheral edge Wp of the substrate W from the outside. Therefore, an energy beam is radiated from the irradiation unit 40 almost uniformly over the entire circumference of the peripheral edge Wp of the substrate W. Therefore, it becomes possible to etch the film on the peripheral edge Wp of the substrate W substantially uniformly at a relatively high etching rate.

### [Modifications]

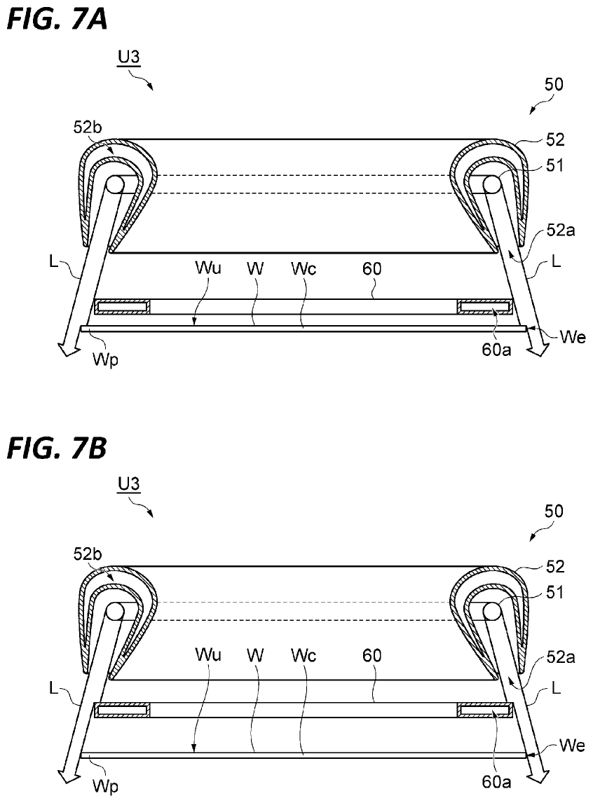

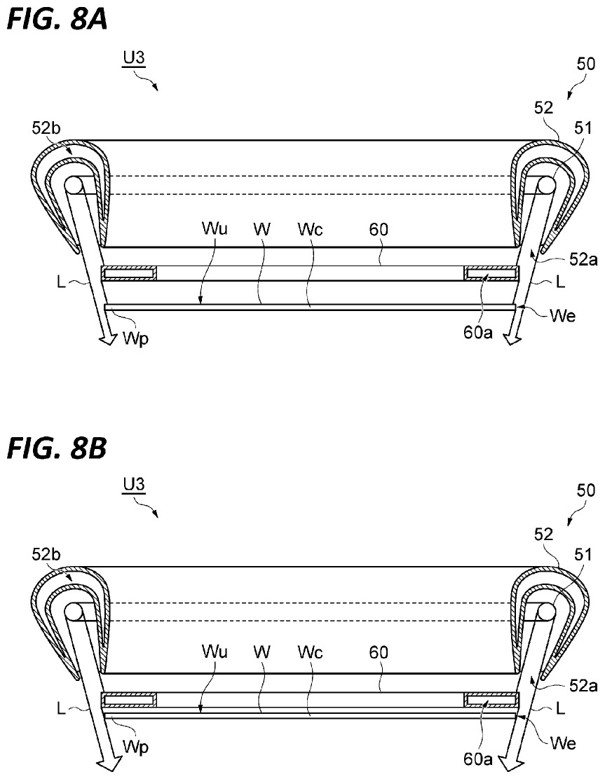

It is to be understood that the disclosure in this specification is exemplary in all respects and is not restrictive. Various omissions, substitutions, changes, and the like may be made to the above examples without departing from the scope and gist of the claims.
(1) As illustrated in FIGS. 7A and 7B, the driving unit 70 may not be connected to the peripheral edge heating unit 50 but may be connected to the light shielding member 60, and may be configured to move the light shielding member 60 up and down. Specifically, as illustrated in FIG. 7A, the driving unit 70 may lower the light shielding member 60 such that the separation distance between the substrate W and the light shielding member 60 decreases. In this case, the light L from the peripheral edge heating unit 50 after being shaped into a shape along the outer peripheral edge of the light shielding member 60 is radiated onto a predetermined region of the peripheral edge Wp of the substrate W. Meanwhile, as illustrated in FIG. 7B, the driving unit 70 may raise the light shielding member 60 such that the separation distance between the substrate W and the light shielding member 60 increases. In this case, the light L from the peripheral edge heating unit 50 after being shaped into a shape along the outer peripheral edge of the light shielding member 60 passes through a space outside the peripheral edge Wp of the substrate W and is not radiated to the peripheral edge Wp of the substrate W.
(2) Although not illustrated, the separation distance between the substrate W and the light shielding member 60 may be changed when the lifting unit 30 raises and lowered the rotary holding unit 10.
(3) As illustrated in FIGS. 8A and 8B, the opening 52a may be open obliquely downward and radially inward of the substrate W. In this case, the light from the light source 51 is radiated obliquely downward and radially inward of the substrate W through the opening 52a. In the example of FIGS. 8A and 8B, the light shielding member 60 has a diameter (outer diameter) larger than the diameter of the substrate W. In the case of the example of FIGS. 8A and 8B as well, the inclination angle θ of the opening 52a with respect to the vertical direction may be, for example, about 1° to 20° or about 2º to 5°.

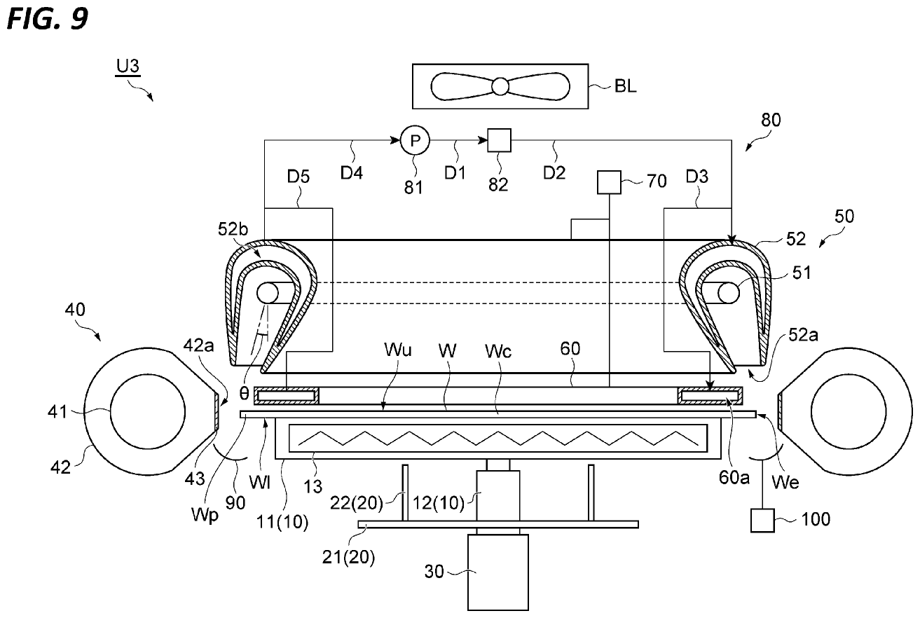

As illustrated in FIG. 7B, the driving unit 70 may raise the light shielding member 60 such that the separation distance between the substrate W and the light shielding member 60 increases. In this case, the light L from the peripheral edge heating unit 50 after being shaped into a shape along the outer peripheral edge of the light shielding member 60 is radiated onto a predetermined region of the peripheral edge Wp of the substrate W. Meanwhile, as illustrated in FIG. 8B, the driving unit 70 may lower the light shielding member 60 such that the separation distance between the substrate W and the light shielding member 60 decreases. In this case, the light L from the peripheral edge heating unit 50 after being shaped into a shape along the outer peripheral edge of the light shielding member 60 passes through a space outside the peripheral edge Wp of the substrate W and is not radiated to the peripheral edge Wp of the substrate W.
(4) As illustrated in FIG. 9, the etching unit U3 may further include a reflective member 90. The reflective member 90 may be located below the peripheral edge Wp of the substrate W. The reflective member 90 may extend in a substantially circular arc shape or a substantially annular shape along the peripheral edge Wp of the substrate W so as to surround the peripheral edge Wp of the substrate W from the outside. Here, the substantially circular arc-shaped reflective member 90 may include a major arc-shaped reflective member 90 that surrounds most of the peripheral edge Wp of the substrate W from the outside but is partially interrupted. The substantially circular arc-shaped reflective member 90 may include a plurality of arc-shaped reflective members 90 that partially surround the peripheral edge Wp of the substrate W from the outside and are aligned along the peripheral edge Wp of the substrate W so as to form a substantially circular shape as a whole. The substantially annular reflective member 90 may include an endless reflective member 90 that surrounds the entire peripheral edge Wp of the substrate W from the outside.

The reflective member 90 is configured to reflect, out of the light radiated from the peripheral edge heating unit 50, an energy beam that has passed outside the peripheral edge Wp of the substrate W, toward the peripheral edge Wp of the substrate W. For example, the reflective member 90 may be configured to mainly reflect, for example, the reflected light, toward the bottom surface Wl and/or the end surface We of the peripheral edge Wp of the substrate W. In this case, the bottom surface Wl and/or the end surface We of the peripheral edge Wp of the substrate W is irradiated with reflected light obtained when the light from the peripheral edge heating unit 50 is reflected on the reflective member 90. Therefore, it becomes possible to etch a film provided from the top surface Wu to the bottom surface Wl of the peripheral edge Wp of the substrate W at substantially the same time. In addition, the region of the reflected light radiated to the bottom surface Wl of the peripheral edge Wp of the substrate may be in a range up to 7 mm from the outer peripheral edge of the substrate W, may be in a range up to 5 mm from the outer peripheral edge of the substrate W, or may be in a range up to 3 mm from the outer peripheral edge of the substrate W.

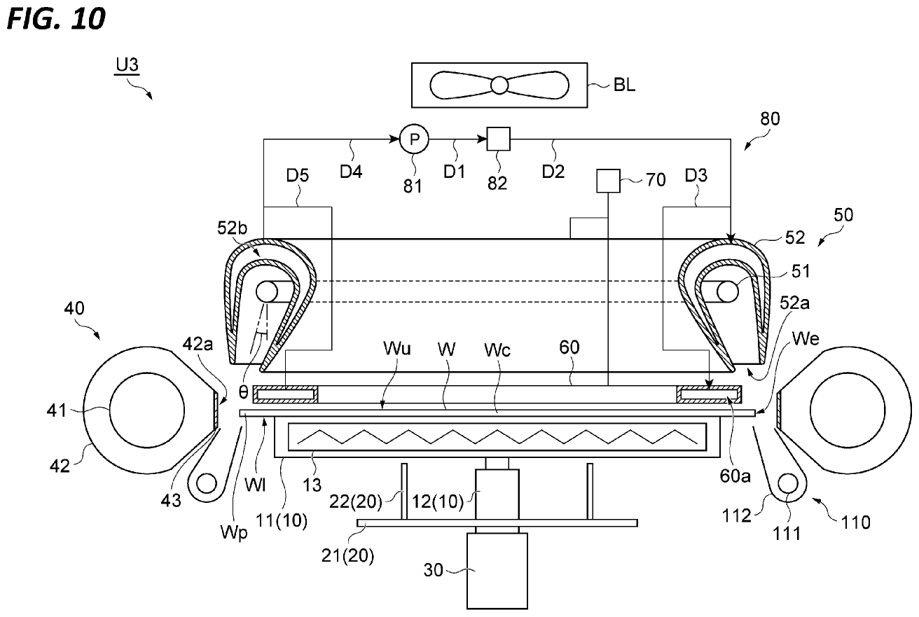

In the example of FIG. 9, the etching unit U3 may further include a driving unit 100 (additional driving unit). The driving unit 100 is configured to operate based on an operation signal from the controller Ctr and change the separation distance between the substrate W and the reflective member 90. The driving unit 100 may be configured with, for example, a linear actuator. As the separation distance between the substrate W and the reflective member 90 is changed by the driving unit 100, the range of the reflected light obtained when the light radiated onto the peripheral edge Wp of the substrate w is reflected from the reflective member 90 changes. Therefore, it becomes possible to appropriately regulate the region in which a relatively hard film provided on the bottom surface of the peripheral edge Wp of the substrate W is etched.
(5) As illustrated in FIG. 10, the etching unit U3 may further include a peripheral edge heating unit 110 (additional peripheral edge heating unit). The peripheral edge heating unit 110 is arranged to be located below the substrate W, and is configured to heat the peripheral edge Wp of the substrate W from below. The peripheral edge heating unit 110 may have a substantially circular arc shape or a substantially annular shape along the peripheral edge Wp of the substrate W, similarly to the peripheral edge heating unit 50. The peripheral edge heating unit 110 may be located so as to overlap the peripheral edge Wp of the substrate W when viewed from above. The peripheral edge heating unit 110 includes a light source 111 and a housing 112.

Like the light source 51, the light source 111 may be an infrared lamp that heats the peripheral edge Wp of the substrate W by radiating light to the peripheral edge Wp. Like the housing 52, the housing 112 may have a substantially U-shaped cross section so as to cover the periphery of the light source 111. That is, the housing 112 may include an opening that is open upward. In this case, the bottom surface Wl and/or the end surface We of the peripheral edge Wp of the substrate W is irradiated with light from the peripheral edge heating unit 110. Therefore, it becomes possible to etch a film provided from the top surface Wu to the bottom surface Wl of the peripheral edge Wp of the substrate W at substantially the same time.

Like the peripheral edge heating unit 50, the peripheral edge heating unit 110 may be raised and lowered by a driving unit (not illustrated). In addition, like the peripheral edge heating unit 50, the peripheral edge heating unit 110 may be configured such that the coolant circulates in the internal space of the housing 112.

Although not illustrated, an additional light shielding member similar to the light shielding member 60 may be arranged between the peripheral edge heating unit 110 and the substrate W. In this case as well, at least a portion of the light from the peripheral edge heating unit 110 is blocked by the additional light shielding member. Therefore, the bottom surface Wl of the peripheral edge part Wp of the substrate W is irradiated with light from the peripheral edge heating unit 110 in a shape along the outer peripheral edge of the additional light shielding member. Therefore, since light is precisely radiated onto the bottom surface Wl of the peripheral edge Wp of the substrate W based on the shape of the outer peripheral edge of the additional light shielding member, it becomes possible to etch a relatively hard film provided on the bottom surface Wl of the peripheral edge Wp of the substrate W with high precision.
(6) In the above examples, air is supplied to the space between the window 43 and the peripheral edge Wp of the substrate W by the blower BL, but an oxygen-containing gas or ozone gas may also be supplied to the space. The oxygen-containing gas may be air or dry air (air that does not contain water vapor or carbon dioxide). Instead of the blower BL, the oxygen-containing gas or ozone gas may be supplied to the space using a gas supply device including a source of the oxygen-containing gas or ozone gas.
(7) In the above examples, the peripheral edge heating unit 50 and the light shielding member 60 are simultaneously cooled by the cooling unit 80, but the cooling unit 80 may be configured to cool at least one of the peripheral edge heating unit 50 and the light shielding member 60. The peripheral edge heating unit 50 and the light shielding member 60 may be cooled separately by two independent cooling units 80.
(8) The light radiated from the peripheral edge heating unit 50 to the peripheral edge Wp of the substrate W may be parallel light, or may be light condensed so as to be focused on the peripheral edge Wp of the substrate W.

### EXPERIMENTAL EXAMPLES

The content of the present technology will be described in more detail below with reference to some experimental results, but the scope and gist of the claims are not limited to the experimental results below.

In the following experimental examples, two types of test pieces were prepared, each having protective films A and B formed of different types of amorphous carbon on its surface. The test pieces were obtained by cutting a substrate W into small pieces. The hardness of the protective film A was smaller than that of the protective film B (softer than the protective film B).

In addition, in the following experimental examples, an etching unit including an irradiation unit disposed above the substrate W was used, unlike the etching unit U3 illustrated in FIG. 3. The irradiation unit included a plurality of straight tube-shaped light sources, a plurality of reflective members, a housing that accommodates the light sources and the reflective members therein, and a window. The plurality of light sources were configured to operate based on operation signals from the controller Ctr and to radiate an ultraviolet beam toward the top surface Wu of the substrate W. The plurality of light sources were aligned at predetermined intervals along a direction parallel to the top surface Wu of the substrate W. Each of the reflective members is located between the corresponding light source and the ceiling wall of the housing, and reflects, toward the window, an energy beam radiated from the light source toward the ceiling wall of the housing. The window was attached to a through-hole provided in the bottom wall of the housing so as to seal the through-hole. The window had a flat shape along the top surface Wu of the substrate W. in addition, the etching unit did not include the peripheral edge heating unit 50, and the test piece held in the holding unit 11 was heated to a predetermined temperature by the center heating unit 13.

### Experimental Example 1

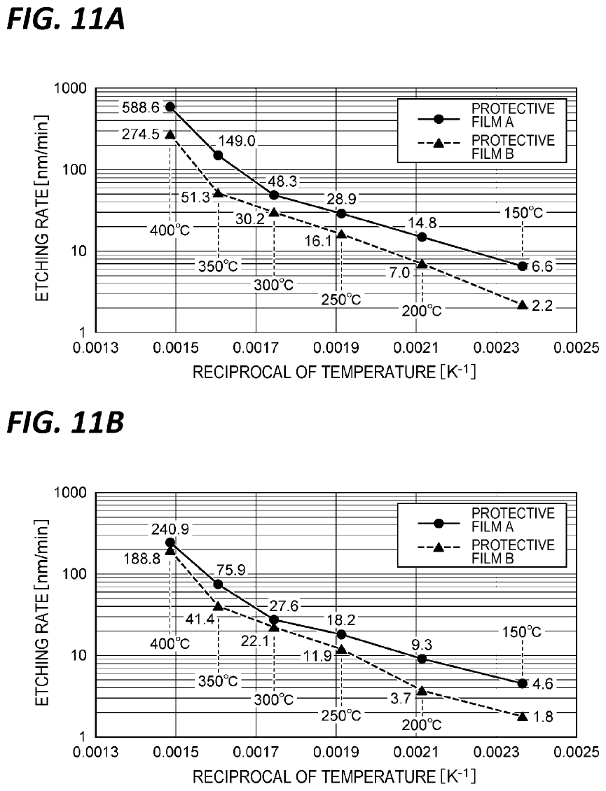

With the gap (straight line distance) between the window and the top surface of the test piece set to 1.2 mm, each test piece was placed on the rotary holding unit 10, and the surface of the test piece was irradiated with an ultraviolet beam from the irradiation unit while dry air was supplied to the space between the window and the rotary holding unit 10. At that time, the test pieces were heated such that the test pieces were heated to different temperatures (150° C., 200° C., 250° C., 300° C., 350° C., and 400° C.), respectively. The results are shown in FIG. 11A. FIG. 11A is a semi-logarithmic graph in which the vertical axis is displayed logarithmically.

As shown in FIG. 11A, it was confirmed that the etching rate increased as the temperature of the test piece became higher. In particular, when the temperature of the test piece was 400° C., the etching rate for the protective film A was 588.6 nm/min, and the etching rate for the protective film B were 274.5 nm/min, so very high etching rates were obtained.

### Experimental Example 2

In Experimental Example 2, the test pieces were processed in the same manner as Experimental Example 1, except that the gap (straight distance) between the window and the top surface of the test piece was set to 2.2 mm. The results are shown in FIG. 11B. FIG. 11B is a semi-logarithmic graph in which the vertical axis is displayed logarithmically. As shown in FIG. 11B, as in Experimental Example 1, in Experimental Example 2 as well, it was confirmed that the etching rate increased as the temperature of the test piece became higher.

### Experimental Example 3

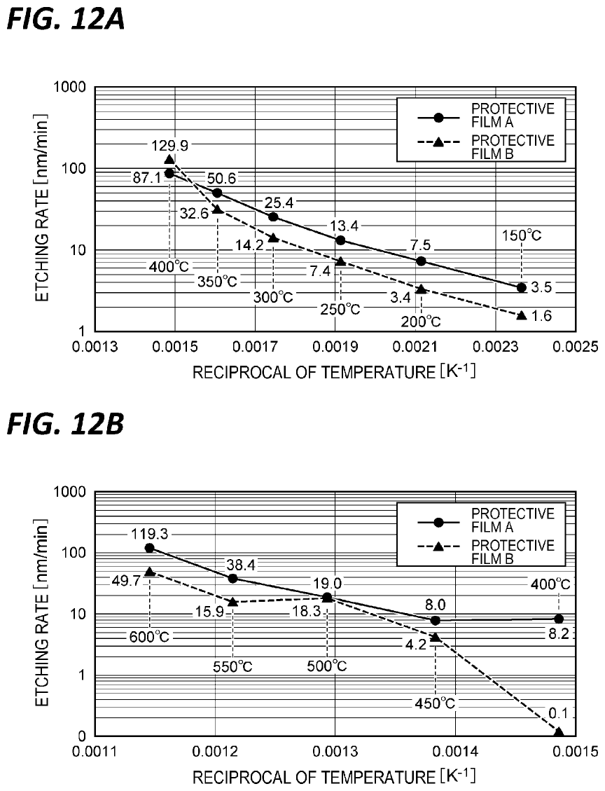

In Experimental Example 3, the test pieces were processed in the same manner as Experimental Example 1, except that the gap (straight distance) between the window and the top surface of the test piece was set to 3.2 mm. The results are shown in FIG. 12A. FIG. 12A is a semi-logarithmic graph in which the vertical axis is displayed logarithmically. As shown in FIG. 12A, as in Experimental Example 1, in Experimental Example 3 as well, it was confirmed that the etching rate increased as the temperature of the test piece became higher.

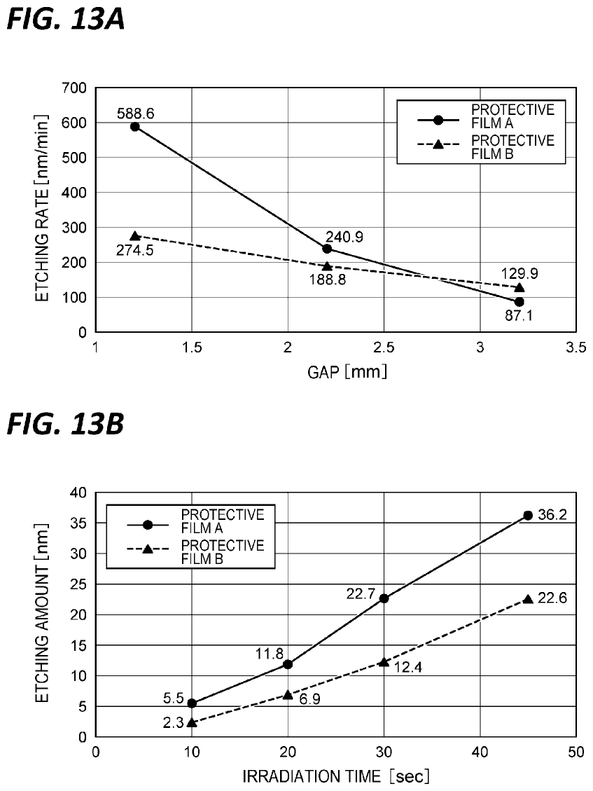

Here, the relationship between the gap and the etching rate when the test piece was heated at 400° C. is shown in FIG. 13A. As shown in FIG. 13A, it was confirmed that in both cases of protective films A and B, the etching rate increased as the gap became smaller. In addition, FIG. 13B shows the relationship between the ultraviolet irradiation time and the etching amount when each test piece was heated at 300° C. with the gap set to 1.2 mm. As shown in FIG. 13B, in both cases of protective films A and B, it was confirmed that the etching amount was approximately proportional to the ultraviolet irradiation time.

### Experimental Example 4

In Experimental Example 4, the test pieces were processed in the same manner as in Experimental Example 1, except that the test pieces were heated to different temperatures (400° C., 450° C., 500° C., 550° C., and 600° C.), respectively, without irradiating the test pieces with an ultraviolet beam from the irradiation unit. That is, each test piece was heated in a dry air atmosphere to etch the protective films A and B. The results are shown in FIG. 12B. That FIG. 12B is a semi-logarithmic graph in which the vertical axis is displayed logarithmically. As shown in FIG. 12B, it was confirmed that as the temperature of the test piece became higher, the etching rate increased, but the etching rate was much lower than in Experimental Examples 1 to 3.

### Experimental Example 5

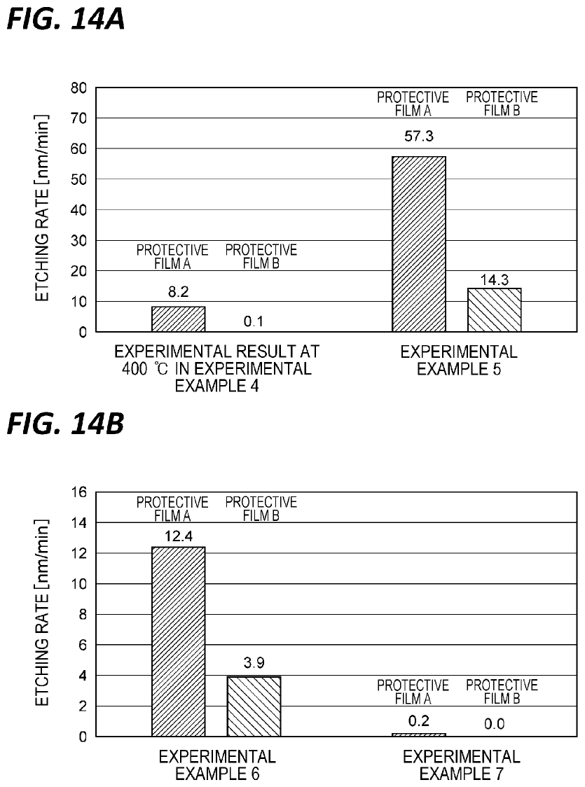

In Experimental Example 5, the test pieces were processed in the same manner as in Example, except that each test piece was heated to 400° C. by irradiating the test piece with an ultraviolet beam from the irradiation unit while blocking the area of the window facing the test piece from light. That is, the protective films A and B were etched by heating the test pieces in an ozone gas atmosphere without directly irradiating the test pieces with an ultraviolet beam. The results are shown in FIG. 14A. As shown in FIG. 14A, it was confirmed that a large etching rate was obtained in an ozone gas atmosphere compared to the results obtained by processing the test pieces at 400° C. in Experimental Example 4.

### Experiment Examples 6 and 7

In Experimental Example 6, the test pieces were processed in the same manner as Experimental Example 1, except that the gap (linear distance) between the window and the top surface of the test piece was set to 1.4 mm, and each test piece was heated to 250° C. In Experimental Example 7, the test pieces were processed in the same manner as Experimental Example 6, except that nitrogen gas was supplied to the space between the window and the rotation holding unit 10. That is, in Experimental Example 7, the test pieces were heated in a nitrogen gas atmosphere to etch the protective films A and B. These results are shown in FIG. 14B. As shown in FIG. 14B, it was confirmed that the etching of the protective films A and B hardly progressed in the nitrogen gas atmosphere.

### Other Examples

Example 1. A substrate processing apparatus includes: an irradiation unit that radiates an etching energy beam having a wavelength of 185 nm or less toward a peripheral edge of a substrate; a gas supply unit that supplies an oxygen-containing gas or ozone gas to the peripheral edge of the substrate; a peripheral edge heating unit that is arranged to be located above the substrate, and extends in a substantially circular arc shape or a substantially annular shape along the peripheral edge of the substrate, and heats the peripheral edge of the substrate by radiating light to the peripheral edge of the substrate; a light shielding member that is disposed between the substrate and the peripheral edge heater, and blocks at least a portion of the light radiated from the peripheral edge heating unit toward the peripheral edge of the substrate; and a driving unit that changes the separation distance between the substrate and the light shielding member. In this case, since the peripheral edge of the substrate is irradiated with a relatively high energy beam having a wavelength of 185 nm or less, the bonds between atoms forming the film provided at the peripheral edge of the substrate can be easily broken. In addition, since an oxygen-containing gas or ozone gas is supplied to the peripheral edge of the substrate, atoms cut by the energy beam tend to bond with oxygen atoms without recombining. Furthermore, since the peripheral edge of the substrate is heated by the peripheral edge heating unit, the cutting of bonds between atoms by the energy beam and the bonding of oxygen atoms to the atoms cut by the energy beam tend to become more active. According to the above, it becomes possible to etch a relatively hard film provided at the peripheral edge of a substrate at a relatively high etching rate without using plasma. In addition, in the case of Example 1, at least a portion of the light radiated from the peripheral edge heating unit toward the peripheral edge of the substrate is blocked by the light shielding member. Therefore, the peripheral edge of the substrate is irradiated with light in a shape along the outer peripheral edge of the light shielding member. Therefore, since the peripheral edge of the substrate is irradiated with light with high precision based on the shape of the outer peripheral edge of the light shielding member, it becomes possible to etch the relatively hard film provided on the peripheral edge of the substrate with high precision. Furthermore, in the case of Example 1, the separation distance between the substrate and the light shielding member is changed by the driving unit. Therefore, in response to this change in separation distance, the range of light radiated from the peripheral edge heating unit to the peripheral edge of the substrate changes. Therefore, it is possible to appropriately adjust the region in which the relatively hard film provided at the peripheral edge of the substrate is etched.
Example 2. In the apparatus of Example 1, the peripheral edge heating unit may include a light source that extends in a substantially circular arc shape or a substantially annular shape along the peripheral edge of the substrate, and a housing that covers the periphery of the light source. The housing may include an opening that is open toward the peripheral edge of the substrate. In this case, the light from the light source and the light reflected on the inner surface of the housing are radiated onto the peripheral edge of the substrate through the opening. Therefore, it becomes possible to efficiently use the optical energy of the light source to heat the peripheral edge of the substrate.
Example 3. In the apparatus of Example 2, the opening may be open obliquely downward. In this case, thanks to the fact that the separation distance between the substrate and the light shielding member is changed by the driving unit, it becomes possible to change the range of light radiated from the peripheral edge heating unit to the peripheral edge of the substrate with higher precision.
Example 4. In the apparatus of Example 3, the opening may be open obliquely downward and radially outward of the substrate, and the light shielding member may have a circular or annular shape with a diameter smaller than the diameter of the substrate. In this case, the same effects as in Example 3 can be obtained.
Example 5. In the apparatus of Example 3, the opening may be open obliquely downward and radially inward of the substrate, and the light shielding member may have a circular or annular shape with a diameter larger than the diameter of the substrate. In this case, the same effects as in Example 3 can be obtained.
Example 6. In the apparatus of one of Examples 1 to 5, the driving unit may be configured to move at least one of the substrate and the light shielding member up and down between a position where the light shielding member blocks the light from the peripheral edge heating unit such that the light from the peripheral edge heating unit does not reach the peripheral edge of the substrate and a position where the light shielding member partially blocks the light from the peripheral edge heating unit such that the light from the peripheral edge heating unit reaches the peripheral edge of the substrate. In this case, while the light irradiation from the peripheral edge heating unit continues, the light reaching the peripheral edge of the substrate is blocked. Therefore, it becomes possible to efficiently process the substrate without waiting for the period during which the light irradiation from the peripheral edge heating unit changes from an off state to an on state and reaches a steady state. Furthermore, it becomes possible to suppress deterioration caused by repeated turning on and off of the light from the peripheral edge heating unit.
Example 7. In the apparatus of one of Examples 1 to 6, the device may further include a rotary holding unit that holds and rotates the substrate. In this case, while the substrate is being rotated, the peripheral edge of the substrate is heated and irradiated with the energy beam. Therefore, heating and energy beam irradiation can be performed substantially uniformly over the entire circumference of the peripheral edge of the substrate. Therefore, it becomes possible to etch the film on the peripheral edge of the substrate substantially uniformly at a relatively high etching rate.
Example 8. The apparatus of one of Examples 1 to 7 may further include a center heating unit that heats the central portion of the substrate, in which the peripheral edge heating unit may be configured to heat the peripheral edge of the substrate to 400° C. or higher, and the center heating unit may be configured to heat the central portion of the substrate to 400° C. or lower. In this case, since the peripheral edge of the substrate is heated to 400° C. or higher, the cutting of bonds between atoms by the energy beam and the bonding of oxygen atoms to the atoms broken by the energy beam tend to become more active. Meanwhile, since the central portion of the substrate is heated to 400° C. or lower, the temperature difference between the peripheral edge and the central portion of the substrate decreases, making it difficult for the substrate to warp. Therefore, thanks to the fact that the amount of heating to the central portion of the substrate is relatively low as well, electronic components formed in the central portion of the substrate are less likely to be damaged. As described above, it becomes possible to etch the film on the peripheral edge of the substrate at a relatively high etching rate while suppressing damage to the electronic components formed in the central portion of the substrate.
Example 9. The apparatus of one of Examples 1 to 8 may further include a reflective member that is arranged to be located below the substrate, and reflects, out of the light radiated from the peripheral edge heating unit, the light that has passed outside the peripheral edge of the substrate toward the peripheral edge of the substrate. In this case, the bottom surface and/or the end surface of the peripheral edge of the substrate is irradiated with reflected light obtained when the light from the peripheral edge heating unit is reflected on the reflective member. Therefore, it becomes possible to etch the film provided from the top surface to the bottom surface of the peripheral edge of the substrate substantially simultaneously.
Example 10. The apparatus of Example 9 may further include an additional driving unit that changes the separation distance between the substrate and the reflective member. In this case, the separation distance between the substrate and the reflective member is changed by the additional driving unit. Therefore, the range of the light reflected from the reflective member and radiated to the peripheral edge of the substrate changes depending on this change in separation distance. Therefore, it becomes possible to appropriately regulate the region in which a relatively hard film provided on the bottom surface of the peripheral edge of the substrate is etched.
Example 11. The device of one of Examples 1 to 8 may further include an additional peripheral edge heating unit that is arranged to be located below the substrate, extends in a substantially circular arc shape or substantially annular shape along the peripheral edge of the substrate, and heats the peripheral edge of the substrate by radiating light to the peripheral edge of the substrate. In this case, the bottom surface and/or the end surface of the peripheral edge of the substrate is irradiated with the light from the additional peripheral edge heating unit. Therefore, it becomes possible to etch the film provided from the top surface to the bottom surface of the peripheral edge of the substrate substantially simultaneously.
Example 12. In the apparatus of one of Examples 1 to 11, the irradiation unit may extend in a substantially circular arc shape or a substantially annular shape along the peripheral edge of the substrate to surround the peripheral edge of the substrate from the outside. In this case, the energy beam is radiated from the irradiation unit almost uniformly over the entire circumference of the peripheral edge of the substrate. Therefore, it becomes possible to etch the film on the peripheral edge of the substrate substantially uniformly at a relatively high etching rate.
Example 13. The apparatus of one of Examples 1 to 12 may further include a cooling unit configured to cool the peripheral edge heating unit and/or the light shielding member by heat exchange with a coolant. In this case, even when the peripheral edge heating unit and/or the light shielding member are heated by light energy radiated from the light source, the heat is cooled by the coolant. Therefore, deformation of the peripheral edge heating unit and/or the light shielding member is suppressed. Therefore, it becomes possible to irradiate the peripheral edge of the substrate with light from the peripheral edge heating unit with higher precision.
Example 14. In the apparatus of one of Examples 1 to 13, the driving unit may be configured to move the light shielding member up and down alone, or may be configured to move the peripheral edge heating unit and the light shielding member up and down together.

With the substrate processing apparatus according to the present disclosure, it is possible to etch a relatively hard film provided at the peripheral edge of a substrate at a relatively high etching rate without using plasma.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
an irradiator configured to radiate an etching energy beam having a wavelength of 185 nm or less toward a peripheral edge of a substrate;
a gas supply configured to supply an oxygen-containing gas or ozone gas to the peripheral edge of the substrate;
a peripheral edge heater arranged to be located above the substrate, extending in a substantially circular arc shape or a substantially annular shape along the peripheral edge of the substrate, and configured to heat the peripheral edge of the substrate by radiating light to the peripheral edge of the substrate;
a light shield disposed between the substrate and the peripheral edge heater, and configured to block at least a portion of the light radiated from the peripheral edge heater toward the peripheral edge of the substrate; and
a driver configured to change a separation distance between the substrate and the light shield.

2. The substrate processing apparatus of claim 1, wherein the peripheral edge heater includes:
a light source extending in a substantially circular arc shape or a substantially annular shape along the peripheral edge of the substrate; and
a housing configured to cover a periphery of the light source, and
wherein the housing includes an opening that is open toward the peripheral edge of the substrate.

3. The substrate processing apparatus of claim 2, wherein the opening is open obliquely downward.

4. The substrate processing apparatus of claim 3, wherein the opening is open obliquely downward and radially outward of the substrate, and
the light shield has a circular or annular shape with a diameter smaller than a diameter of the substrate.

5. The substrate processing apparatus of claim 3, wherein the opening is open obliquely downward and radially inward of the substrate, and
the light shield has a circular or annular shape with a diameter larger than a diameter of the substrate.

6. The substrate processing apparatus of claim 1, wherein the driver is configured to move at least one of the substrate and the light shield up and down between a first position where the light shield blocks the light from the peripheral edge heater such that the light from the peripheral edge heater does not reach the peripheral edge of the substrate and a second position where the light shield partially blocks the light from the peripheral edge heater such that the light from the peripheral edge heater reaches the peripheral edge of the substrate.

7. The substrate processing apparatus of claim 1, further comprising:
a rotary holder configured to hold and rotate the substrate.

8. The substrate processing apparatus of claim 1, further comprising:
a center heater configured to heat a central portion of the substrate,
wherein the peripheral edge heater is configured to heat the peripheral edge of the substrate to 400° C. or higher, and
the center heater is configured to heat the central portion of the substrate to 400° C. or lower.

9. The substrate processing apparatus of claim 1, further comprising:
a reflector arranged to be located below the substrate, and configured to reflect, out of the light radiated from the peripheral edge heater, light that has passed outside the peripheral edge of the substrate toward the peripheral edge of the substrate.

10. The substrate processing apparatus of claim 9, further comprising:
an additional driver configured to change a separation distance between the substrate and the reflector.

11. The substrate processing apparatus of claim 1, further comprising:
an additional peripheral edge heater arranged to be located below the substrate, extending in a substantially circular arc shape or a substantially annular shape along the peripheral edge of the substrate, and configured to heat the peripheral edge of the substrate by radiating light to the peripheral edge of the substrate.

12. The substrate processing apparatus of claim 1, wherein the irradiator extends in a substantially circular arc shape or a substantially annular shape along the peripheral edge of the substrate to surround the peripheral edge of the substrate from an outside.

13. The substrate processing apparatus of claim 1, further comprising:
a cooler configured to cool the peripheral edge heater and/or the light shield by heat exchange with a coolant.

14. The substrate processing apparatus of claim 1, wherein the driver is configured to move the light shield up and down alone, or to move the peripheral edge heater and the light shield up and down together.
